(19) United States
(12) Patent Application Publication
(10) Pub. No.: US 2025/0287604 A1
(43) Pub. Date: Sep. 11, 2025

(54) MEMORY DEVICES WITH PROGRAMMABLE GATES

(71) Applicant: Intel Corporation, Santa Clara, CA (US)

(72) Inventor: Abhishek A. Sharma, Portland, OR (US)

(73) Assignee: Intel Corporation, Santa Clara, CA (US)

(21) Appl. No.: 18/598,086

(22) Filed: Mar. 7, 2024

(51) Int. Cl. H10B 51/30; H10B 43/10; H10B 43/30; H10B 51/10

(52) U.S. Cl. CPC H10B 51/30; H10B 43/10; H10B 43/30; H10B 51/10

(57) ABSTRACT

Integrated circuit (IC) structures implementing memory devices with programmable gates are disclosed. An example IC structure includes a substrate and a stack comprising a plurality of nanoribbons that are vertically stacked above one another over the substrate. In a cross-section of the IC structure along a plane perpendicular to a longitudinal axis of the stack and including vertically stacked portions of the plurality of nanoribbons of the stack, the IC structure includes an insulator material between adjacent nanoribbons of the stack, a first conductive material extending vertically along a first sidewall or a second sidewall of the stack, and a second conductive material extending vertically along the first sidewall or the second sidewall of the stack, wherein the second conductive material is electrically isolated from the first conductive material.

### BACKGROUND

Floating body memory is a type of non-volatile memory that relies on the charge storage in a floating body layer. While it has some potential advantages over other memory types, such as low power consumption and compatibility with standard semiconductor manufacturing processes, there are several challenges associated with its implementation and, therefore, further improvements are desirable.

### BRIEF DESCRIPTION OF THE DRAWINGS

Embodiments will be readily understood by the following detailed description in conjunction with the accompanying drawings.

FIG. 1 provides a perspective view of an example integrated circuit (IC) structure implementing a nanoribbon-based field-effect transistor (FET), according to some embodiments of the present disclosure.

FIGS. 2A-2F illustrate cross-sectional side views and top-down views of example IC structures memory devices at various stages of fabrication according to the first embodiment.

FIGS. 3A-3F illustrate cross-sectional side views and top-down views of example IC structures memory devices at various stages of fabrication according to the second embodiment.

FIGS. 4A-4C illustrate cross-sectional side views and top-down views of example IC structures memory devices at various stages of fabrication according to the third embodiment.

FIGS. 5A-5C illustrate cross-sectional side views and top-down views of example IC structures memory devices at various stages of fabrication according to the fourth embodiment.

FIGS. 6A-6B illustrate cross-sectional side views and top-down views of example IC structures memory devices at various stages of fabrication according to the fifth embodiment.

FIG. 7 provides top views of a wafer and dies that may include one or more memory devices with programmable gates in accordance with any of the embodiments disclosed herein.

FIG. 8 is a cross-sectional side view of an IC package that may include one or more memory devices with programmable gates in accordance with any of the embodiments disclosed herein.

FIG. 9 is a cross-sectional side view of an IC device assembly that may include one or more memory devices with programmable gates in accordance with any of the embodiments disclosed herein.

FIG. 10 is a block diagram of an example computing device that may include one or more memory devices with programmable gates in accordance with any of the embodiments disclosed herein.

FIG. 11 is a block diagram of an example processing device that may include one or more memory devices with programmable gates in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating memory devices with programmable gates as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Some memory devices may be considered “standalone” devices in that they are included in a chip that does not also include compute logic (where, as used herein, the term “compute logic devices” or simply “compute logic” or “logic devices,” refers to IC components, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Access transistors have been used in the past to realize memory where each memory cell includes one capacitor for storing a memory state (e.g., logical “1” or “0”) of the cell and an access transistor controlling access to the cell (e.g., access to write information to the cell or access to read information from the cell). Such a memory cell may be referred to as a “1T-1C memory cell,” highlighting the fact that it uses one access transistor (i.e., “1T” in the term “1T-1C memory cell”) and one capacitor (i.e., “1C” in the term “1T-1C memory cell”). One capacitor electrode of the capacitor of a 1T-1C memory cell may be coupled to one of a source region or a drain region of the access transistor (e.g., to the source region of the access transistor), while the other one of a source region or a drain region of the access transistor (e.g., to the drain region) may be coupled to a first control line (e.g., a bitline). Because the designation of “source” and “drain” in a transistor may be interchangeable, in the following, source regions and drain regions of a transistor are referred to as a “first S/D region” and a “second S/D region,” where one of the first and second S/D regions is a source region and the other one is a drain region. A gate of the access transistor of a 1T-1C memory cell may be coupled to a second control line (e.g., a wordline), and the other capacitor electrode of the capacitor may be coupled to a third control line (e.g., a plateline). Voltages may then be applied to the first, second, and third control lines to read and write data of such a 1T-1C memory cell. Since such a memory cell can be fabricated with as little as a single access transistor, it can provide higher density and lower standby power versus some other types of memory in the same process technology.

Floating body memory, e.g., floating body dynamic random-access memory (FBDRAM) is a popular choice for various types of computer systems because it is even simpler than 1T-1C memory in that it only uses a single transistor as a memory cell. Thus, such memory cells may be referred to as “1T” memory cells. In floating body memory, a memory cell (also referred to as a “floating body memory cell”) may use the floating body of a single transistor to store data, which, compared to 1T-1C memory, eliminates the need to use a capacitor to store charge representing a memory state. In a conventional floating body memory cell, a first S/D region is coupled to a first control line (e.g., a bitline), a second S/D region is coupled to a second control line (e.g., a selectline), and a gate of the transistor is coupled to a third control line (e.g., a wordline). Voltages may then be applied to the first, second, and third control lines to read and write data of such a floating body memory cell.

In some deployment scenarios, floating body memory cells may be more advantageous than traditional memory cells, given their simple structure and high scalability. One challenge resides in that, given a usable surface area of a support structure such as a substrate, a die, a wafer, or a chip, there are only so many floating body memory cells that can be formed in that area, placing a limitation on the density of floating body memory arrays. In the past, attempts to increase memory density included decreasing the critical dimensions of individual components of memory cells (e.g., decreasing transistor dimensions), which requires ever-increasing process complexity and cost, resulting in diminishing returns and expected slow pace of memory scaling for future nodes. Therefore, other past attempts to increase memory density included increasing the number of active memory layers by fabricating vertically-stacked floating body memory cells using stacks of nanoribbons (i.e., where transistors of the memory cells were nanoribbon-based transistors), thus implementing three-dimensional (3D) vertically-stacked floating body memory.

Embodiments of the present disclosure are based on recognition that, to make floating body memory cells even more advantageous, it would be desirable to add another layer of programmability by implementing additional control lines coupled to individual memory cells of 3D vertically-stacked floating body memory. However, this is not trivial, especially when memory cells are implemented with stacks of nanoribbons where the vertical distance between adjacent nanoribbons of a given stack is smaller than the horizontal distance between adjacent stacks.

Embodiments of the present disclosure may improve on at least some of the challenges and issues described above by providing memory devices with programmable gates utilizing 1T memory cells, and by disclosing several fabrication methods for fabricating such memory devices using fewer masks and at a lower cost. In some of the embodiments, an example 1T memory cell may include a transistor having channel regions in multiple nanoribbons of a single stack of vertically-stacked nanoribbons. In other embodiments, an example 1T memory cell may include a transistor having channel regions in multiple nanoribbons of two adjacent stacks of vertically-stacked nanoribbons. In various embodiments, a gate of the transistor of a 1T memory cell may be coupled to two control lines that may be individually controlled (such control lines referred to in the following as “gate control lines”). For example, the two gate control lines coupled to an individual gate may be electrically isolated from one another and coupled to respective (i.e., different) signal sources. A gate of such a transistor may be described as “programmable” because two gate control lines coupled to the gate provide additional degrees of freedom in controlling the gate. For example, the first gate control line may be used to turn the gate on and off, while the second gate control line may be used to set the work function of the gate. As is known in the art, in the context of FETs, the term “work function” refers to the minimum energy required to move an electron from the source region to the channel region of a transistor. To that end, the work function of a gate electrode material used to implement the gate is significant because it determines the energy barrier for electrons to tunnel through the gate insulator and to influence the conductivity of the channel. In a conventional 1T memory cell with only one gate control line coupled to a gate, when a voltage is applied to the gate using this control line, it creates an electric field that controls the flow of charge carriers (electrons or holes) in the channel, but the work function of the gate may not be changed. In sharp contrast to such conventional 1T memory cells, memory cells as described herein provide a second gate control line that may allow changing the work function. In other examples, the second gate control line of memory cells with programmable gates as described herein may be used to control the number of charges in the channel, which may help control conductivity of the channel, or to reduce the fields across gate insulators, which may help improve endurance and reliability of memory cells by reducing the likelihood of the dielectric breakdown of gate insulators.

In one aspect, a memory device with a programmable gate may be implemented as an IC structure that includes a substrate (or, more generally, a support structure that may be a substrate, a wafer, a chip, or a die) and a stack comprising a plurality of nanoribbons that are vertically stacked above one another over the substrate. In the context of the present disclosure, the term “above” may refer to being further away from the substrate of an IC structure, while the term “below” refers to being closer towards the substrate. In a cross-section of the IC structure along a plane perpendicular to a longitudinal axis of the stack and including vertically-stacked portions of the plurality of nanoribbons of the stack, the IC structure includes an insulator material between adjacent nanoribbons of the stack, a first conductive material extending vertically along a first sidewall or a second sidewall of the stack, and a second conductive material extending vertically along the first sidewall or the second sidewall of the stack, wherein the second conductive material is electrically isolated from the first conductive material. The first conductive material may be coupled to, or may implement, a first gate control line coupled to the gate of a transistor, while the second conductive material may be coupled to, or may implement, a second gate control line coupled to the gate of the transistor. Because the second conductive material is electrically isolated from the first conductive material, the first and a second gate control lines may be individually controllable, thus realizing a memory device with a programmable gate.

Memory devices with programmable gates as described herein may be used to address the scaling challenges of conventional memory technologies and enable high density embedded memory compatible with advanced complementary metal-oxide-semiconductor (CMOS) processes. Other technical effects will be evident from various embodiments described here.

In the following detailed description, various aspects of the illustrative implementations may be described using terms commonly employed by those skilled in the art to convey the substance of their work to others skilled in the art. For example, in context of S/D regions, the term “region” may be used interchangeably with the terms “contact” and “terminal” of a transistor. As used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. As used herein, A connected to B may includes A being in physical contact (e.g., in direct physical contact) with B; if one or more interfacial layers may form when A and B are brought into direct physical contact, then such interfacial layers may be considered to be a part of A and/or a part of B. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

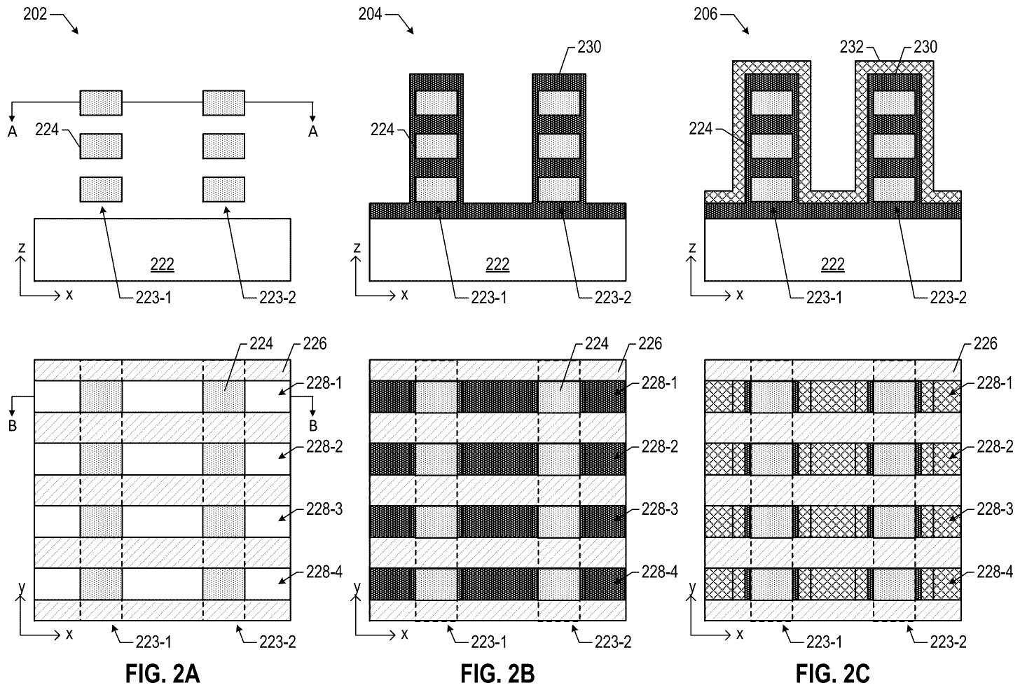

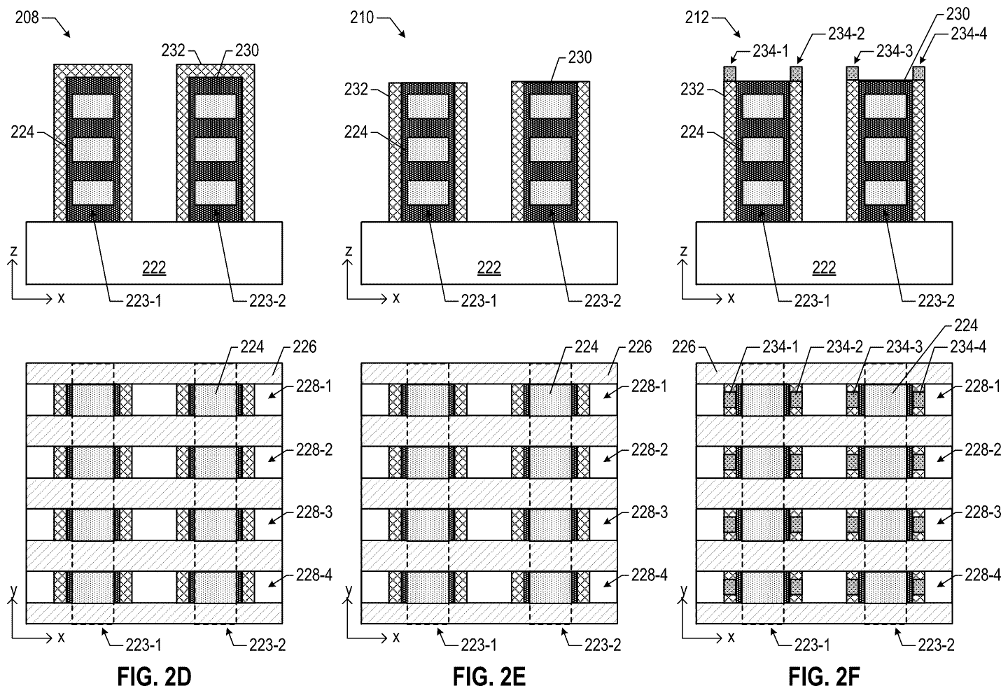

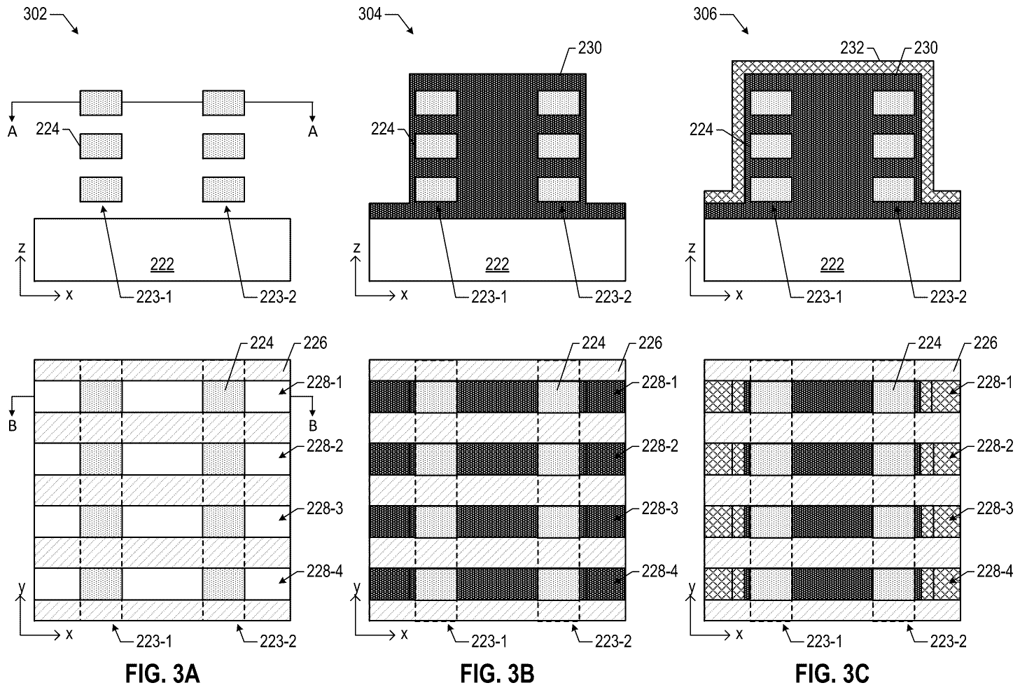

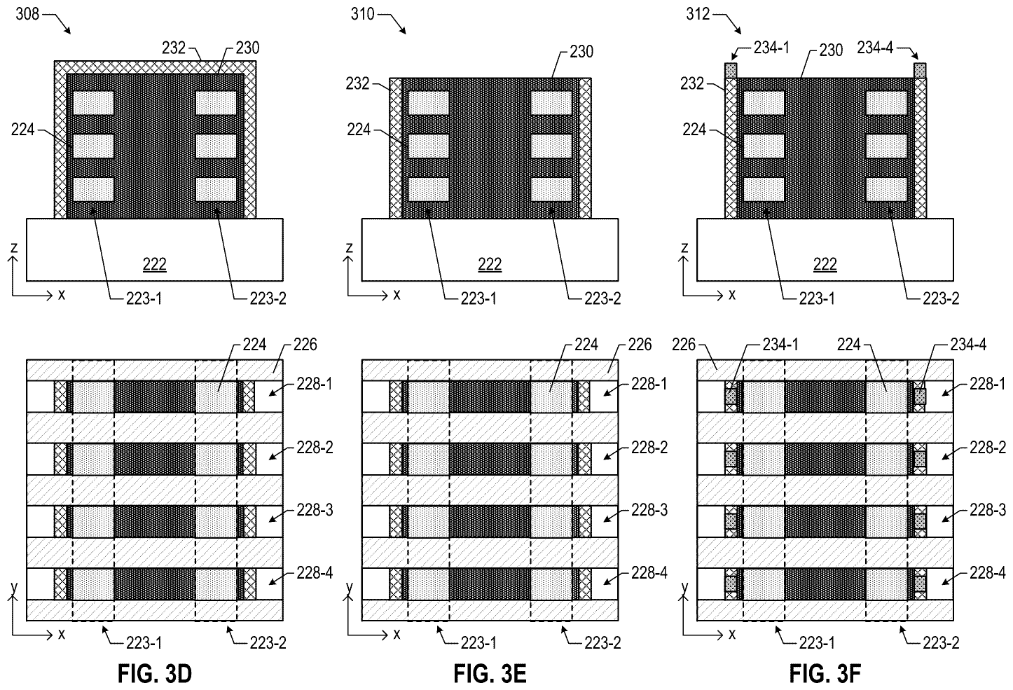

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, analogous elements designated in the present drawings with different reference numerals after a dash, e.g., first and second S/D regions 114-1, 114-2 may be referred to together without the reference numerals after the dash, e.g., as “S/D regions 114.” In order to not clutter the drawings, if multiple instances of certain elements are illustrated, only some of the elements may be labeled with a reference sign. For convenience, the phrase “FIG. 2” may be used to refer to the collection of drawings of FIGS. 2A-2F, the phrase “FIG. 3” may be used to refer to the collection of drawings of FIGS. 3A-3F, etc.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of memory devices with programmable gates as described herein.

Various memory devices with programmable gates as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

Nanoribbon-based transistors may be particularly advantageous for continued scaling of CMOS technology nodes due to the potential to form gates on all four sides of a channel material (hence, such transistors are sometimes referred to as “gate all around” transistors). As used herein, the term “nanoribbon” refers to an elongated structure of a semiconductor material having a longitudinal axis parallel to a support structure (e.g., a substrate, a die, a chip, or a wafer; also referred to herein as, simply, “support”) over which such a structure is built. Typically, a length of a such a structure (i.e., a dimension measured along the longitudinal axis, shown in the present drawings to be along the y-axis of an example x-y-z coordinate system) is greater than each of a width (i.e., a dimension measured along the x-axis of the example coordinate system shown in the present drawings) and a thickness/height (i.e., a dimension measured along the z-axis of the example coordinate system shown in the present drawings). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon-based transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain (S/D) regions of a transistor provided on either side of the channel material.

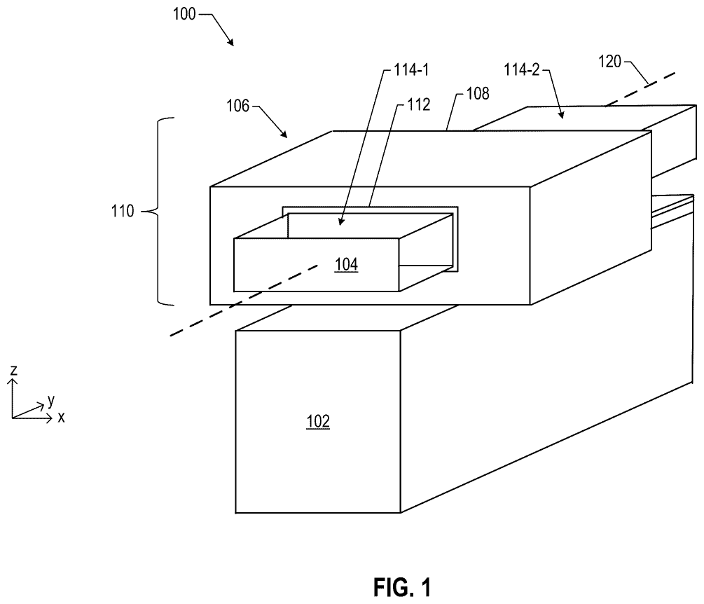

FIG. 1 provides a perspective view of an example IC structure 100 with a nanoribbon-based transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” or a “channel region” and by having source and drain regions, shown in FIG. 1 as a first S/D region 114-1 and a second S/D region 114-2 (together referred to as “S/D regions 114”), on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

The nanoribbon 104 may take the form of a nanowire or nanoribbon, for example. In some embodiments, an area of a transversal cross-section of the nanoribbon 104 (i.e., an area in the x-z plane of the example coordinate system x-y-z shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the y-axis of the example coordinate system shown in FIG. 1) may be at least about 3 times larger than a height of the nanoribbon 104 (i.e., a dimension measured in a plane perpendicular to the support 102, e.g., along the z-axis of the example coordinate system shown in FIG. 1), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” (e.g., a bottom face and a top face) of a nanoribbon may refer to sides of the nanoribbon 104 that are substantially parallel to the support 102, while the term “sidewall” (e.g., left sidewall and right sidewall) of a nanoribbon may refer to sides of the nanoribbon 104 that are between the bottom and top faces of the nanoribbon 104. Although only one nanoribbon 104 is shown in FIG. 1, the IC structure 100 may include a stack of such nanoribbons where a plurality of nanoribbons 104 are stacked above one another, e.g., as is shown in FIGS. 2-6. In some embodiments, a portion of the support 102 right below the lowest nanoribbon 104 of the stack may be shaped as a subfin extending away from a base, as is known in the field of nanoribbon-based transistors.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back end fabrication to avoid damaging other components, e.g., front end components such as the logic devices.

A gate stack 106 including a gate electrode material 108 and, optionally, a gate insulator 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator 112 may wrap around a transversal portion of the nanoribbon 104 and the gate electrode material 108 may wrap around the gate insulator 112.

The gate electrode material 108 may include at least one p-type work function metal or n-type work function metal, depending on whether the transistor of which it is a part is to be a PMOS or an NMOS transistor. For example, a p-type work function metal may be used as the gate electrode material 108 when the transistor 110 is a PMOS transistor and an n-type work function metal may be used as the gate electrode material 108 when the transistor 110 is an NMOS transistor. For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further metal layers may be included for other purposes, such as a barrier layer (e.g., tantalum, tantalum nitride, an aluminum-containing alloy, etc.). In some embodiments, a gate electrode material 108 may include a resistance-reducing cap layer (e.g., copper, gold, cobalt, or tungsten). Further layers may be included next to the gate electrode material 108 for other purposes, such as to act as a diffusion barrier layer or/and an adhesion layer.

In some embodiments, the gate insulator 112 may include one or more high-k dielectrics, e.g., insulator materials including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator 112 during fabrication of the transistor 110 to improve the quality of the gate insulator 112. The gate insulator 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and source/drain contacts of the transistor 110 and could be made of a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. A gate spacer may include pores or air gaps to further reduce its dielectric constant.

In some embodiments, e.g., when the transistor 110 is a storage transistor of a hysteretic memory cell (i.e., a type of memory that functions based on the phenomenon of hysteresis), the gate insulator 112 may be replaced with, or complemented by, a hysteretic material or a hysteretic arrangement, which, together, may be referred to as a “hysteretic element.” Transistors 110 in which the gate insulator 112 includes a hysteretic element may be described as “hysteretic transistors” and may be used to implement hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a voltage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high speed writing. In addition, hysteretic memories may be manufactured using processes compatible with the standard CMOS technology. Therefore, over the last few years, these types of memories have emerged as promising candidates for many growing applications.

In some embodiments, the hysteretic element of the gate insulator 112 may be provided as a layer of a FE or an AFE material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator 112 may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge-trapping may be used to represent different memory states of a memory cell.

In some embodiments of the hysteretic element being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

Turning to the S/D regions 114 of the transistor 110, in some embodiments, the S/D regions may be highly doped, e.g., with dopant concentrations of at least about 1×10¹⁸ dopants per cubic centimeter (cm⁻³), e.g., of at least about 1×10²⁰ cm⁻³, or of at least about 1×10²¹ cm⁻³, in order to advantageously form Ohmic contacts with the respective S/D electrodes (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” regions. Even with doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC devices/structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D electrode (which may also be referred to as a “first S/D contact”) coupled to a first S/D region 114-1 of the transistor 110 and the gate stack 106 as well as between a second S/D electrode (which may also be referred to as a “second S/D contact”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric. In other embodiments, the insulator material surrounding portions of the transistor 110 may be a low-k dielectric material.

An IC structure 100 shown in FIG. 1 may be used as a starting point for describing IC structures implementing memory devices with programmable gates. More specifically, memory devices with programmable gates as proposed herein may be built by modifying the IC structure 100 as described below.

FIGS. 2-6 illustrate example IC structures with memory devices at various stages of fabrication according to various embodiments. In particular, each of FIGS. 2-6, e.g., each of FIGS. 2A-2F, each of FIGS. 3A-3F, etc., illustrates a cross-sectional side view (a cross-section in an x-z plane of the example coordinate system shown in FIG. 1) and a corresponding top-down view (a cross-section in an x-y plane of the example coordinate system shown in FIG. 1) of an IC structure providing a memory device, where the top-down view is a view along a plane AA shown in the cross-sectional side view of FIG. 2A, and the cross-sectional side view is a view along a cross-section of a plane BB shown in the top-down view of FIG. 2A. The cross-sectional side views shown in FIGS. 2-6 are cross-sections of the IC structures along a plane perpendicular to a longitudinal axis of an individual stack of nanoribbons (where the longitudinal axis of the stack may extend in the direction of the longitudinal axis 120 described above) and including vertically-stacked portions of the plurality of nanoribbons of the stack. In the top-down views of FIGS. 2-6, when nanoribbons are obscured by other materials deposited over them, outlines of the nanoribbons are shown with dashed lines (thus, nanoribbons extend along the y-axis of the example coordinate system, as shown in FIGS. 2-6). The planes AA and BB are not shown in other ones of FIGS. 2-6 except for FIG. 2A in order to not clutter the drawings.

FIGS. 2A-2F illustrate cross-sectional side views and top-down views of example memory devices at various stages of fabrication according to the first embodiment.

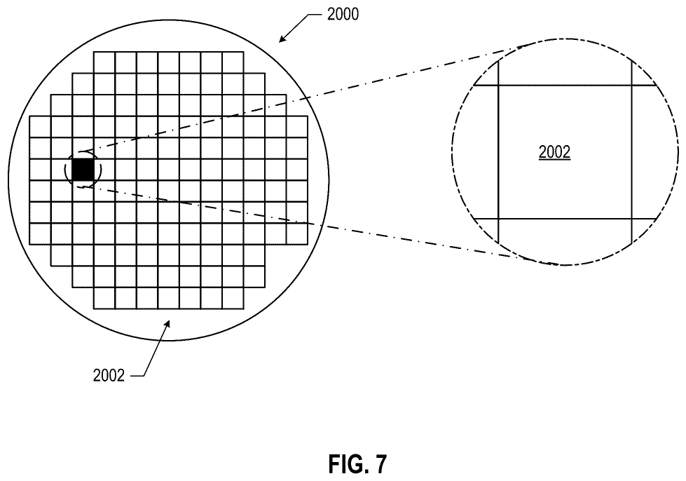

FIG. 2A illustrates an IC structure 202 that includes a support 222 and stacks 223 of nanoribbons 224. Implementations of the present disclosure may be formed or carried out on any suitable support 222, such as a substrate, a die, a wafer, or a chip. The support 222 may, e.g., be the wafer 2000 of FIG. 7, discussed below, and may be, or be included in, a die, e.g., the singulated die 2002 of FIG. 7, discussed below. The support 222 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 222 may be a printed circuit board (PCB) substrate, a package substrate, an interposer, a wafer, or a die. Although a few examples of materials from which the support 222 may be formed are described here, any material that may serve as a foundation upon which an IC structure with one or more memory devices with programmable gates as described herein may be built falls within the spirit and scope of the present disclosure.

Descriptions provided for the nanoribbon 104 of FIG. 1 are applicable to the nanoribbons 224 and, for the sake of brevity, are not repeated. Although two stacks 223, each including four nanoribbons 224 are shown in FIG. 2A and subsequent drawings of FIGS. 2-6, in other embodiments, different number of stacks 223 may be included as part of memory devices with programmable gates, and/or an individual stack 223 may include different number of nanoribbons 224 than what is shown in FIGS. 2-6. In some embodiments, a portion of the support 222 right below the lowest nanoribbon 224 of an individual stack 223 may be shaped as a subfin extending away from a base, as is known in the field of nanoribbon-based transistors.

As shown in FIG. 2A, the nanoribbons 224 may be surrounded by an insulator material 226 with one or more openings 228 (shown in FIG. 2A as openings 228-1, 228-2, 228-3, and 228-4) provided in the insulator material 226 around channel portions of future transistors, as is known in fabrication of nanoribbon-based transistors. The openings 228 are shown in FIG. 2A as openings 228-1, 228-2, 228-3, and 228-4, but other number of the openings 228 may be included in other embodiments. In some embodiments, the insulator material 226 may be a low-k dielectric material, e.g., any of the low-k dielectric materials described above. In some embodiments, the insulator material 226 may include pores or air gaps to further reduce its dielectric constant.

The fabrication according to the first embodiment may then proceed with depositing an insulator material on sidewalls of the stacks 223 and in between the nanoribbons 224 of an individual stack 223. A result of this process is shown in FIG. 2B, illustrating an IC structure 204 that is substantially the same as the IC structure 202 but further including an insulator material 230 on the sidewalls of the stacks 223-1 and 223-2, at the support 222 outside of the stacks 223, and between the nanoribbons 224 of each of the stacks 223. In some embodiments, the insulator material 230 may fill all space between the adjacent nanoribbons 224 of an individual stack 223 so that when a conductive material is deposited in a subsequent process (e.g., in the process shown in FIG. 2C), there is no conductive material between the adjacent nanoribbons 224 of the stack 223. This is in contrast to conventional floating body memory cells where the conductive material of a wordline would wrap around individual vertically-stacked portions of the plurality of nanoribbons of a stack. As shown in FIG. 2B, the insulator material 230 may be deposited directly on and around the nanoribbons 224 exposed by the openings 228 and, therefore, be in contact with sidewalls and faces of the channel portions of the nanoribbons 224. The insulator material 230 may be deposited using any suitable conformal deposition techniques in some embodiments, such as atomic layer deposition (ALD), or chemical vapor deposition (CVD). In some embodiments, a thickness of the insulator material 230 on the sidewalls of the stacks 223 may be between about 0.5 nanometers and 10 nanometers, including all values and ranges therein (e.g., between about 1 and 3 nanometers, or between about 1 and 2 nanometers). In some embodiments, the insulator material 230 may include any of the materials described with reference to the gate insulator 112. In other embodiments, the insulator material 230 may be a low-k dielectric material, e.g., any of the low-k dielectric materials described above.

Next, the fabrication according to the first embodiment may proceed with depositing a conductive material to cover the stacks 223. A result of this process is shown in FIG. 2C, illustrating an IC structure 206 that is substantially the same as the IC structure 204 but further including a conductive material 232 on the sidewalls of the stacks 223-1 and 223-2, on the top of the stacks 223, and at the support 222 outside of the stacks 223. Because the insulator material 230 was deposited first, the conductive material 232 may be deposited on all of the exposed surfaces of the insulator material 230. Thus, e.g., at the sidewalls of the stacks 223, the insulator material 230 may be between (and in physical contact with) the sidewalls of the nanoribbons 224 on one side and the conductive material 232 on the other side. The conductive material 232 may be deposited using techniques such as ALD, CVD, physical vapor deposition (PVD), or sputtering. In some embodiments, a thickness of the conductive material 232 on the sidewalls of the stacks 223 may be between about 5 nanometers and 100 nanometers, including all values and ranges therein (e.g., between about 5 and 50 nanometers, or between about 5 and 25 nanometers). In some embodiments, the conductive material 232 may include any of the materials described with reference to the gate electrode material 108.

The fabrication according to the first embodiment may then proceed with removing the insulator material 230 and the conductive material 232 that was deposited over the support 222 outside of the stacks 223. A result of this process is shown in FIG. 2D, illustrating an IC structure 208 that is substantially the same as the IC structure 206 but with the insulator material 230 and the conductive material 232 removed between and around the stacks 223. Any suitable technique may be used to that end, e.g., any suitable etching technique such as anisotropic etching.

The fabrication according to the first embodiment may also include removing the conductive material 232 from the tops of the stacks 223 without substantially removing the insulator material 230. A result of this process is shown in FIG. 2E, illustrating an IC structure 210 that is substantially the same as the IC structure 208 but with the conductive material 232 removed from the tops of the stacks 223, exposing the insulator material 230 at the tops of the stacks 223. Any suitable technique may be used to that end, e.g., any suitable polishing technique. As FIG. 2E illustrates, as a result of removing the conductive material 232 from the tops of the stacks 223 portions of the conductive material 232 on opposite sidewalls of the stacks 223 are no longer materially and electrically continuous. Thus, as shown in the cross-section of FIG. 2E, for the stack 223-1, a first portion of the conductive material 232 extends vertically along the first sidewall of the stack 223-1 (e.g., the left sidewall), while a second portion of the conductive material 232 extends vertically along the second sidewall of the stack 223-1 (e.g., the right sidewall), where the first and second portions of the conductive material 232 are electrically isolated from one another. In particular, because the insulator material 230 is deposited between the nanoribbons 224 of the stack 223-1, no conductive material 232 is present there and, thus, the insulator material 230 provides the electrical isolation between the first and second portions of the conductive material 232 on the opposite sidewalls of the stack 223-1. Analogous applies to the stack 223-2.

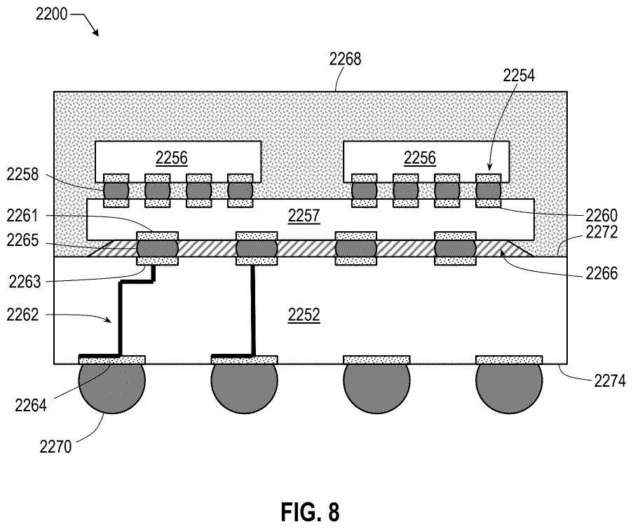

Individual gate control lines may then be coupled to the portions of the conductive material 232 on the opposite sidewalls of an individual stack 223. A result of this process is shown in FIG. 2F, illustrating an IC structure 212 that is substantially the same as the IC structure 210 but with conductive contacts 234 coupled to respective electrically isolated from one another portions of the conductive material 232. In particular, FIG. 2F illustrates a conductive contact 234-1 connected (e.g., being in conductive contact with) to the first portion of the conductive material 232 extending vertically along the first sidewall of the stack 223-1, a conductive contact 234-2 connected (e.g., being in conductive contact with) to the second portion of the conductive material 232 extending vertically along the second sidewall of the stack 223-1, a conductive contact 234-3 connected (e.g., being in conductive contact with) to the first portion of the conductive material 232 extending vertically along the first sidewall of the stack 223-2, and a conductive contact 234-4 connected (e.g., being in conductive contact with) to the second portion of the conductive material 232 extending vertically along the second sidewall of the stack 223-2. Descriptions provided for conductive contacts of FIG. 8 are applicable to the conductive contacts 234.

For the stack 223-1, the conductive contact 234-1 and the first portion of the conductive material 232 extending vertically along the first sidewall of the stack 223-1 may be considered to be, or may be coupled to (e.g., may be in conductive contact with) a first gate control line coupled to the channel region in the stack 223-1 in an individual opening 228. Similarly, the conductive contact 234-2 and the second portion of the conductive material 232 extending vertically along the second sidewall of the stack 223-1 may be considered to be, or may be coupled to (e.g., may be in conductive contact with) a second gate control line coupled to the channel region in the stack 223-1 in an individual opening 228. Thus, according to the first embodiment illustrated in FIG. 2F, two individually controllable (i.e., electrically isolated from one another) gate control lines are coupled to a single channel region in the stack 223-1 in the opening 228-1. For example, signals (e.g., voltages) applied to the conductive contact 234-1 may be used to turn a gate formed in the opening 228-1 around the nanoribbons 224 of the stack 223-1 on and off, while signals (e.g., voltages) applied to the conductive contact 234-2 may be used to set the work function of the gate. In other examples, for the transistors implemented in the stack 223-1, signals applied to one of the conductive contacts 234-1 and 234-2 of FIG. 2F may be used to control the number of charges in the channel portion in the stack 223-1 in the opening 228-1, which may help control conductivity of the channel, or to reduce the fields across the insulator material 230, which may help improve endurance and reliability of memory cells by reducing the likelihood of the dielectric breakdown of the insulator material 230.

Similarly, for the stack 223-2 of FIG. 2F, the conductive contact 234-3 and the first portion of the conductive material 232 extending vertically along the first sidewall of the stack 223-2 may be considered to be, or may be coupled to (e.g., may be in conductive contact with) a first gate control line coupled to the channel region in the stack 223-2 in an individual opening 228. Similarly, the conductive contact 234-4 and the second portion of the conductive material 232 extending vertically along the second sidewall of the stack 223-2 may be considered to be, or may be coupled to (e.g., may be in conductive contact with) a second gate control line coupled to the channel region in the stack 223-2 in an individual opening 228. Thus, according to the first embodiment illustrated in FIG. 2F, two individually controllable (i.e., electrically isolated from one another) gate control lines are coupled to a single channel region in the stack 223-2 in the opening 228-1. For example, signals (e.g., voltages) applied to the conductive contact 234-3 may be used to turn a gate formed in the opening 228-1 around the nanoribbons 224 of the stack 223-2 on and off, while signals (e.g., voltages) applied to the conductive contact 234-4 may be used to set the work function of the gate. In other examples, for the transistors implemented in the stack 223-2, signals applied to one of the conductive contacts 234-3 and 234-4 of FIG. 2F may be used to control the number of charges in the channel portion in the stack 223-2 in the opening 228-1, which may help control conductivity of the channel, or to reduce the fields across the insulator material 230, which may help improve endurance and reliability of memory cells by reducing the likelihood of the dielectric breakdown of the insulator material 230.

FIGS. 3A-3F illustrate cross-sectional side views and top-down views of example IC structures memory devices at various stages of fabrication according to the second embodiment.

The fabrication according to the second embodiment may begin in the same manner as fabrication according to the first embodiment. A result of this process is shown in FIG. 3A, illustrating an IC structure 302 that is substantially the same as the IC structure 202, described above.

The fabrication according to the second embodiment may then proceed with depositing an insulator material on sidewalls of the stacks 223 and in between the nanoribbons 224 of individual stacks 223, as in the fabrication of the first embodiment, and further depositing the insulator material between the adjacent stacks 223. A result of this process is shown in FIG. 3B, illustrating an IC structure 304 that is substantially the same as the IC structure 204 of FIG. 2B, described above, but further including the insulator material 230 between the stack 223-1 and the stack 223-2. As shown in FIG. 3B, the insulator material 230 may fill all space between the adjacent nanoribbons 224 of the stack 223-1, between the adjacent nanoribbons of the stack 223-2, and between the stacks 223. A thickness of the insulator material 230 at the left sidewall of the stack 223-1 and at the right sidewall of the stack 223-2 of the embodiment shown in FIG. 3B may be as that described above for the first embodiment.

Next, the fabrication according to the second embodiment may proceed with depositing a conductive material to cover the stacks 223. A result of this process is shown in FIG. 3C, illustrating an IC structure 306 that is substantially the same as the IC structure 304 but further including a conductive material 232 on the left sidewall of the stack 223-1 and the right sidewall of the stack 223-2, on the top of the stacks 223, over the insulator material 230 between the stacks 223, and at the support 222 outside of the stacks 223. Similar to the embodiment shown in FIG. 2C, in FIG. 3C, because the insulator material 230 was deposited first, the conductive material 232 may be deposited on all of the exposed surfaces of the insulator material 230 of the previous IC structure (i.e., of the IC structure 304). Thus, e.g., at the left sidewall of the stack 223-1 and at the right sidewall of the stack 223-2, the insulator material 230 may be between (and in physical contact with) the sidewalls of the nanoribbons 224 on one side and the conductive material 232 on the other side. On these sidewalls, the conductive material 232 may have a thickness as described above for the first embodiment.

The fabrication according to the second embodiment may then proceed with removing the insulator material 230 and the conductive material 232 that was deposited over the support 222 outside of the stacks 223. A result of this process is shown in FIG. 3D, illustrating an IC structure 308 that is substantially the same as the IC structure 306 but with the insulator material 230 and the conductive material 232 removed outside of the stacks 223 but, in contrast to the embodiment shown in FIG. 2D, not between the stacks 223. Any suitable technique may be used to that end, e.g., any suitable etching technique such as anisotropic etching.

The fabrication according to the second embodiment may also include removing the conductive material 232 from the tops of the stacks 223 and from the top of the insulator material 230 between the stacks 223 without substantially removing the insulator material 230. A result of this process is shown in FIG. 3E, illustrating an IC structure 310 that is substantially the same as the IC structure 308 but with the conductive material 232 removed from the tops of the stacks 223 and from the top of the insulator material 230 between the stacks 223, exposing the insulator material 230 at the tops of and between the stacks 223. Any suitable technique may be used to that end, e.g., any suitable polishing technique. As FIG. 3E illustrates, as a result of removing the conductive material 232 from the tops of the stacks 223 portions of the conductive material 232 on opposite sidewalls of the stack 223-1 and the stack 223-2 are no longer materially and electrically continuous. Thus, as shown in the cross-section of FIG. 3E, a first portion of the conductive material 232 extends vertically along the first sidewall of the stack 223-1 (e.g., the left sidewall), while a second portion of the conductive material 232 extends vertically along the second sidewall of the stack 223-2 (e.g., the right sidewall), where the first and second portions of the conductive material 232 are electrically isolated from one another. As shown in FIG. 3E, the first sidewall of the stack 223-1 is further away from the stack 223-2 than a second sidewall of the stack 223-1, and the second sidewall of the stack 223-2 is further away from the stack 223-1 than the first sidewall of the stack 223-2. Similar to the first embodiment, because the insulator material 230 is deposited between the nanoribbons 224 of the stack 223-1, between the nanoribbons 224 of the stack 223-2, and, different from the first embodiment, also between the stacks 223-1 and 223-2, no conductive material 232 is present these regions and, thus, the insulator material 230 provides the electrical isolation between the first and second portions of the conductive material 232 on the opposite sidewalls of the stacks 223-1 and 223-2 of FIG. 3E.

Individual gate control lines may then be coupled to the portions of the conductive material 232 on the opposite sidewalls of the stacks 223-1 and 223-2 of FIG. 3E. A result of this process is shown in FIG. 3F, illustrating an IC structure 312 that is substantially the same as the IC structure 310 but with conductive contacts 234 coupled to respective electrically isolated from one another portions of the conductive material 232. In particular, FIG. 3F illustrates a conductive contact 234-1 connected (e.g., being in conductive contact with) to the first portion of the conductive material 232 extending vertically along the first sidewall of the stack 223-1, and a conductive contact 234-4 connected (e.g., being in conductive contact with) to the second portion of the conductive material 232 extending vertically along the second sidewall of the stack 223-2.

The conductive contacts 234-1 and 234-4 of FIG. 3F are substantially the same as the conductive contacts 234-1 and 234-4 of FIG. 2F, described above, except for the following differences. Similar to FIG. 2F, in FIG. 3F, the conductive contact 234-1 and the first portion of the conductive material 232 extending vertically along the left sidewall of the stack 223-1 may be considered to be, or may be coupled to (e.g., may be in conductive contact with) a first gate control line coupled to the channel region in an individual opening 228. However, because the insulator material 230 is between the stack 223-1 and the stack 223-2 in FIG. 3F, the channel region in an individual opening 228 may include channel regions in both the stack 223-1 and the stack 223-2, and the conductive contacts 234-2 and 234-3 of FIG. 2F are absent in FIG. 3F. Instead, the conductive contact 234-4 and the second portion of the conductive material 232 extending vertically along the right sidewall of the stack 223-2 may be considered to be, or may be coupled to (e.g., may be in conductive contact with) a second gate control line coupled to the channel region in the individual opening 228. Thus, according to the second embodiment, illustrated in FIG. 3F, two individually controllable (i.e., electrically isolated from one another) gate control lines may be coupled to a single channel region. For example, signals (e.g., voltages) applied to the conductive contact 234-1 may be used to turn a gate formed in the opening 228-1 around the nanoribbons 224 of the stacks 223-1 and 223-2 on and off, while signals (e.g., voltages) applied to the conductive contact 234-4 may be used to set the work function of the gate. In other examples, signals applied to one of the conductive contacts 234-1 and 234-4 of FIG. 3F may be used to control the number of charges in the channel portion in the stacks 223-1 and 223-2 in the opening 228-1, which may help control conductivity of the channel, or to reduce the fields across the insulator material 230, which may help improve endurance and reliability of memory cells by reducing the likelihood of the dielectric breakdown of the insulator material 230.

Phrased differently, one difference between the embodiment shown in FIG. 2F and that shown in FIG. 3F is that, in FIG. 2F, two transistors are provided within an individual opening 228 (e.g., in the opening 228-1), where the first transistor has a channel portion in portions of the nanoribbons 224 of the stack 223-1 within the individual opening 228, and the second transistor has a channel portion in portions of the nanoribbons 224 of the stack 223-2 within the individual opening 228. Two individually controllable gate control lines are then coupled to the channel portion of each of the two such transistors, represented in FIG. 2F with two individually controllable conductive contacts 234-1 and 234-2 coupled to the channel portion of the first transistor in the individual opening 228, and with two individually controllable conductive contacts 234-3 and 234-4 coupled to the channel portion of the second transistor in the individual opening 228. In some embodiments of FIG. 3F, however, a single transistor may be provided within an individual opening 228 (e.g., in the opening 228-1), where the single transistor has a channel portion in portions of the nanoribbons 224 of the stack 223-1 as well as in portions of the nanoribbons 224 of the stack 223-2 within the individual opening 228. Two individually controllable gate control lines are then coupled to the channel portion of such a transistor, represented in FIG. 3F with two individually controllable conductive contacts 234-1 and 234-4 coupled to the channel portion of the single transistor in an individual opening 228. In both FIG. 2F and FIG. 3F, first and second S/D regions of the transistors may be in portions of the nanoribbons 224 in planes in front and behind the plane of the cross-sectional side view of FIG. 2F and FIG. 3F, e.g., as described above with reference to the S/D regions 114-1 and 114-2 shown in FIG. 1. In other embodiments of FIG. 3F, the channel portion in portions of the nanoribbons 224 of the stack 223-1 and in portions of the nanoribbons 224 of the stack 223-2 within an individual opening 228 may be shared among two different transistors, as long as at least one of their S/D regions are separate, or different, from one another.

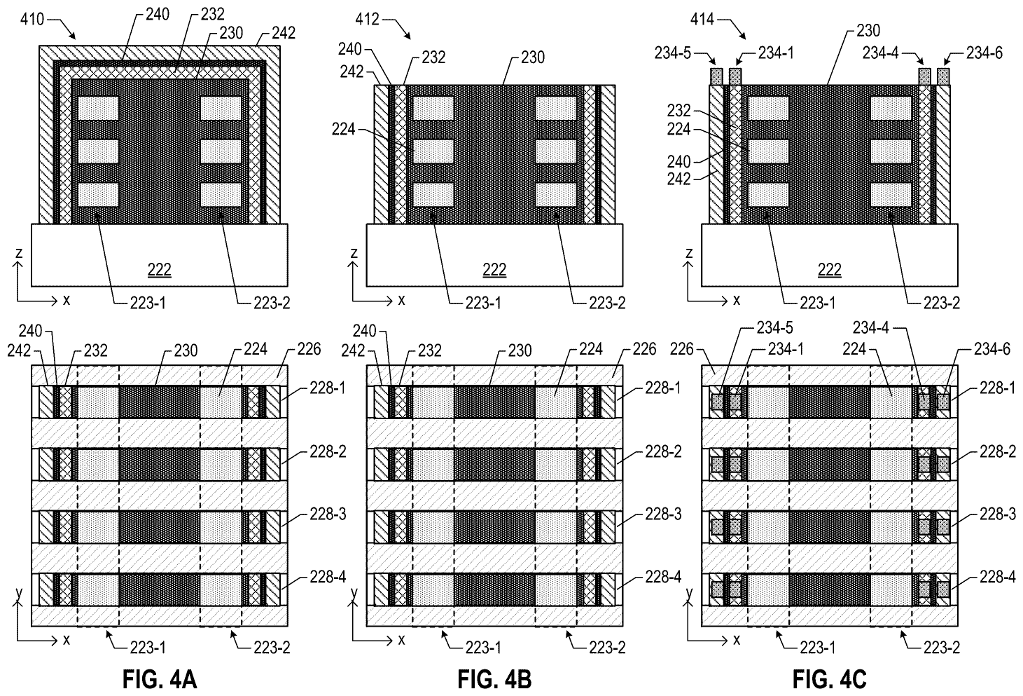

FIGS. 4A-4C illustrate cross-sectional side views and top-down views of example IC structures memory devices at various stages of fabrication according to the third embodiment.

The fabrication according to the third embodiment may begin in the same manner as fabrication according to the second embodiment and proceed up to and including a fabrication process as described with reference to FIG. 3D. Thus, FIGS. 4A-4C illustrate results of the processes starting with the IC structure 308 of FIG. 3D.

Once the IC structure 308 of FIG. 3D has been fabricated, the fabrication according to the third embodiment may include processes to enclose the conductive material 232 of the IC structure 308 with a second insulator material 240 and enclose the second insulator material 240 with a second conductive material 242. A result of this process is shown in FIG. 4A, illustrating an IC structure 410 that is substantially the same as the IC structure 308, described above, but further including a second insulator material 240 around the conductive material 232, as well as a second conductive material 242 around the second insulator material 240. Any suitable techniques may be used to fabricate the IC structure 410 as shown in FIG. 4A, so that the conductive material 232 is between, and may be in direct physical contact with, the insulator material 230 and the second insulator material 240, and so that the second insulator material 240 is between, and may be in direct physical contact with, the conductive material 232 and the second conductive material 242. The second conductive material 242 may include any of the materials described with reference to the conductive material 232, and, in various embodiments, material compositions of the second conductive material 242 and the conductive material 232 may be the same or different. Similarly, the second insulator material 240 may include any of the materials described with reference to the insulator material 230, and, in various embodiments, material compositions of the second insulator material 240 and the insulator material 230 may be the same or different. In some embodiments, one of the insulator material 230 and the second insulator material 240 may include a ferroelectric or an antiferroelectric material, while the other one may include a dielectric material that is not a ferroelectric or an antiferroelectric material. A thickness of the second insulator material 240 at the left sidewall of the stack 223-1 and at the right sidewall of the stack 223-2 of the embodiment shown in FIG. 4A may be as that described above for the second embodiment. Similarly, a thickness of the second conductive material 242 at the left sidewall of the stack 223-1 and at the right sidewall of the stack 223-2 of the embodiment shown in FIG. 4A may be as that described above for the second embodiment.

The fabrication according to the third embodiment may further include removing the second conductive material 242, the second insulator material 240, and the conductive material 232 from the tops of the stacks 223 and from the top of the insulator material 230 between the stacks 223 without substantially removing the insulator material 230. A result of this process is shown in FIG. 4B, illustrating an IC structure 412 that is substantially the same as the IC structure 410 but with the second conductive material 242, the second insulator material 240, and the conductive material 232 removed from the tops of the stacks 223 and from the top of the insulator material 230 between the stacks 223, exposing the insulator material 230 at the tops of and between the stacks 223. Any suitable technique may be used to that end, e.g., any suitable polishing technique. As FIG. 4B illustrates, as a result of removing all layers to expose the insulator material 230 at the tops of and between the stacks 223, portions of the conductive material 232 on opposite sidewalls of the stack 223-1 and the stack 223-2 are no longer materially and electrically continuous, and portions of the second conductive material 242 on opposite sidewalls of the stack 223-1 and the stack 223-2 are no longer materially and electrically continuous. Thus, as shown in the cross-section of FIG. 4B, a first portion of the conductive material 232 extends vertically along the first sidewall of the stack 223-1 (e.g., the left sidewall), while a second portion of the conductive material 232 extends vertically along the second sidewall of the stack 223-2 (e.g., the right sidewall), where the first and second portions of the conductive material 232 are electrically isolated from one another by the insulator material 230. Furthermore, as also shown in the cross-section of FIG. 4B, a first portion of the second conductive material 242 extends vertically along the first sidewall of the stack 223-1 (e.g., the left sidewall), while a second portion of the second conductive material 242 extends vertically along the second sidewall of the stack 223-2 (e.g., the right sidewall), where the first portion of the second conductive material 242 and the first portion of the conductive material 232 are electrically isolated from one another by a portion of the second insulator material 240 extending vertically along the left sidewall of the stack 223-1, and where the second portion of the second conductive material 242 and the second portion of the conductive material 232 are electrically isolated from one another by a portion of the second insulator material 240 extending vertically along the right sidewall of the stack 223-2. Similar to FIG. 3E, in FIG. 4B, the first sidewall of the stack 223-1 is further away from the stack 223-2 than a second sidewall of the stack 223-1, and the second sidewall of the stack 223-2 is further away from the stack 223-1 than the first sidewall of the stack 223-2. Similar to the second embodiment, because the insulator material 230 is deposited between the nanoribbons 224 of the stack 223-1, between the nanoribbons 224 of the stack 223-2, and also between the stacks 223-1 and 223-2, no conductive material 232 is present these regions and, thus, the insulator material 230 provides the electrical isolation between the first and second portions of the conductive material 232 on the opposite sidewalls of the stacks 223-1 and 223-2 of FIG. 4B.

Individual gate control lines may then be coupled to the portions of the conductive material 232 and the second conductive material 242 on the opposite sidewalls of the stacks 223-1 and 223-2 of FIG. 4B. A result of this process is shown in FIG. 4C, illustrating an IC structure 414 that is substantially the same as the IC structure 412 but with conductive contacts 234 coupled to respective electrically isolated from one another portions of the conductive material 232 and the second conductive material 242. In particular, FIG. 4C illustrates conductive contacts 234-1 and 234-4 as described with reference to FIG. 3F, and further illustrates a conductive contact 234-5 connected (e.g., being in conductive contact with) to the first portion of the second conductive material 242 extending vertically along the first sidewall of the stack 223-1, and a conductive contact 234-6 connected (e.g., being in conductive contact with) to the second portion of the second conductive material 242 extending vertically along the second sidewall of the stack 223-2.

The conductive contacts 234-1 and 234-4 of FIG. 4C are substantially the same as the conductive contacts 234-1 and 234-4 of FIG. 3F, described above. Thus, similar to FIG. 3F, in FIG. 4C, the conductive contact 234-1 and the first portion of the conductive material 232 extending vertically along the left sidewall of the stack 223-1 may be considered to be, or may be coupled to (e.g., may be in conductive contact with) a first gate control line coupled to the channel region in an individual opening 228, and the conductive contact 234-4 and the second portion of the conductive material 232 extending vertically along the right sidewall of the stack 223-2 may be considered to be, or may be coupled to (e.g., may be in conductive contact with) a second gate control line coupled to the channel region in the individual opening 228. Similar to FIG. 3F, in FIG. 4C, because the insulator material 230 is between the stack 223-1 and the stack 223-2 in FIG. 4C, the channel region in an individual opening 228 includes channel regions in both the stack 223-1 and the stack 223-2, and the conductive contacts 234-2 and 234-3 of FIG. 2F are absent in FIG. 4C. Different from FIG. 3F, in FIG. 4C, the conductive contact 234-5 and the first portion of the second conductive material 242 extending vertically along the left sidewall of the stack 223-1 may be considered to be, or may be coupled to (e.g., may be in conductive contact with) a third gate control line coupled to the channel region in an individual opening 228, and the conductive contact 234-6 and the second portion of the second conductive material 242 extending vertically along the right sidewall of the stack 223-2 may be considered to be, or may be coupled to (e.g., may be in conductive contact with) a fourth gate control line coupled to the channel region in the individual opening 228. Thus, according to the third embodiment, illustrated in FIG. 4C, four individually controllable (i.e., electrically isolated from one another) gate control lines are coupled to a single channel region. For example, in FIG. 4C, signals (e.g., voltages) applied to one of the conductive contacts 234-1, 234-4, 234-5, and 234-6 may be used to turn a gate formed in the opening 228-1 around the nanoribbons 224 of the stacks 223-1 and 223-2 on and off, while signals (e.g., voltages) applied to another one of the conductive contacts 234-1, 234-4, 234-5, or 234-6 may be used to set the work function of the gate. In other examples, signals applied to one of the conductive contacts 234-1, 234-4, 234-5, and 234-6 of FIG. 4C may be used to control the number of charges in the channel portion in the stacks 223-1 and 223-2 in the opening 228-1, which may help control conductivity of the channel, or to reduce the fields across the insulator material 230, which may help improve endurance and reliability of memory cells by reducing the likelihood of the dielectric breakdown of the insulator material 230. In some embodiments of FIG. 4C, the conductive contacts 234-1 and 234-4 may be floating (e.g., not electrically connected to any signal or ground sources), while signals (e.g., voltages) applied to the conductive contacts 234-5 and/or 234-6 may be used to provide charge into the conductive contacts 234-1 and 234-4 by tunnelling. After the charge has been lodged into the conductive contacts 234-1 and 234-4, it may remain there for a period of time, defining/setting the threshold voltage of the transistor. In other embodiments of FIG. 4C, the conductive contacts 234-1 and 234-4 may be used to apply bias to program (i.e., write) the bits of the floating body memory cells, while the conductive contacts 234-5 and 234-6 may be used to read the bits. Reading of memory bits typically happens more frequent than writing and, therefore, may lead to a dielectric breakdown. Using the conductive contacts 234-5 and 234-6 to read the bits may reduce the electric field across the insulator material 230, which may help improve endurance and reliability of the memory cells.

Similar to FIG. 3F, in some embodiments of FIG. 4C, a single transistor may be provided within an individual opening 228 (e.g., in the opening 228-1), where the single transistor has a channel portion in portions of the nanoribbons 224 of the stack 223-1 as well as in portions of the nanoribbons 224 of the stack 223-2 within the individual opening 228. In contrast to FIG. 3F, in FIG. 4C, four individually controllable gate control lines are then coupled to the channel portion of such a transistor, represented in FIG. 4C with four individually controllable conductive contacts 234-1, 234-4, 234-5, and 234-6 coupled to the channel portion of the single transistor in an individual opening 228. Similar to FIG. 3F, in FIG. 4C, first and second S/D regions of the transistor may be in portions of the nanoribbons 224 in planes in front and behind the plane of the cross-sectional side view of FIG. 4C, e.g., as described above with reference to the S/D regions 114-1 and 114-2 shown in FIG. 1. In other embodiments of FIG. 4C, the channel portion in portions of the nanoribbons 224 of the stack 223-1 and in portions of the nanoribbons 224 of the stack 223-2 within an individual opening 228 may be shared among two different transistors, as long as at least one of their S/D regions are separate, or different, from one another.

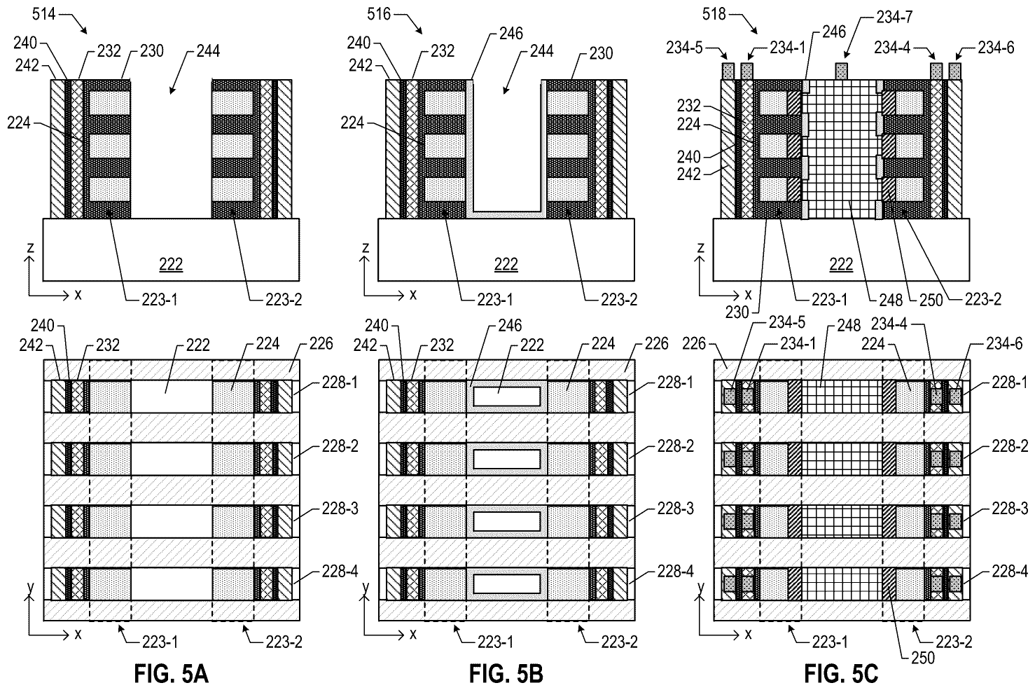

FIGS. 5A-5C illustrate cross-sectional side views and top-down views of example IC structures memory devices at various stages of fabrication according to the fourth embodiment.

The fabrication according to the fourth embodiment may begin in the same manner as fabrication according to the third embodiment and proceed up to and including a fabrication process as described with reference to FIG. 4B. Thus, FIGS. 5A-5C illustrate results of the processes starting with the IC structure 412 of FIG. 4B.

Once the IC structure 412 of FIG. 4B has been fabricated, the fabrication according to the fourth embodiment may include a process to remove the insulator material 230 between the stacks 223-1 and 223-2. A result of this process is shown in FIG. 5A, illustrating an IC structure 514 that is substantially the same as the IC structure 412, described above, but further including openings 244 between the stacks 223-1 and 223-2 in the openings 228, with the support 222 being at the bottom of the openings 244. As shown in FIG. 5A, as a result of removing the insulator material 230 between the stacks 223-1 and 223-2, opposing sidewalls of the nanoribbons 224 of the stacks 223-1 and 223-2 may be exposed at the sidewalls of the openings 244.

The fabrication according to the fourth embodiment may then proceed with depositing a liner of an insulator material on sidewalls and, optionally, the bottoms of the openings 244. A result of this process is shown in FIG. 5B, illustrating an IC structure 516 that is substantially the same as the IC structure 514 but further including an insulator material 246. The insulator material 246 may include any suitable insulator material, e.g., any of the low-k dielectric materials described herein. A thickness of the insulator material 246 may be between about 5 nanometers and 100 nanometers, including all values and ranges therein, e.g., between about 5 nanometers and 50 nanometers, or between about 10 nanometers and 30 nanometers. Any suitable techniques may be used to deposit the insulator material 246, e.g., any suitable conformal deposition technique such as ALD or CVD.

The fabrication according to the third embodiment may further include patterning the insulator material 246 to expose sidewalls of the nanoribbons 224 of the stacks 223-1 and 223-2 that were exposed at the sidewalls of the openings 244, then depositing a conductive material into the openings 244, and forming conductive contacts. A result of this process is shown in FIG. 5C, illustrating an IC structure 518 that is substantially the same as the IC structure 516 but where the insulator material 246 is patterned so that it only remains in contact with the insulator material 230 at the sidewalls of the openings 244 but is removed from the sidewalls of the nanoribbons 224 at the sidewalls of the openings 244, thus exposing the sidewalls of the nanoribbons 224 in the openings 244. FIG. 5C further illustrates a conductive material 248 deposited within the openings 244 once the insulator material 246 has been patterned. FIG. 5C further illustrates conductive contacts 234-1, 234-4, 234-5, and 234-6 as described above (e.g., as described with reference to FIG. 4C), as well as a conductive contact 234-7 coupled to the conductive material 248. In FIG. 5C, the conductive contact 234-7 and the conductive material 248 in one of the openings 244 in an individual opening 228 may be considered to be, or may be coupled to (e.g., may be in conductive contact with) a S/D control line coupled to first S/D regions 250 of a first transistor having a channel region in the nanoribbons 224 of the stack 223-1 and/or coupled to first S/D regions 250 of a second transistor having a channel region in the nanoribbons 224 of the stack 223-1. The first S/D regions 250 of the first and second transistors are illustrated as portions of the nanoribbons 224 adjacent to the sidewalls of the openings 244. The first S/D regions 250 may be highly doped regions, e.g., as described above with reference to the S/D regions 114. For example, the first S/D regions 250 may be portions of the nanoribbons 224 that include one or more semiconductor materials with dopant atoms in a concentration of at least 1×10¹⁸ dopant atoms per cubic centimeter.

Thus, in FIG. 5C, two transistors are provided within an individual opening 228 (e.g., in the opening 228-1), where the first transistor has a channel portion in portions of the nanoribbons 224 of the stack 223-1 within the individual opening 228, and the second transistor has a channel portion in portions of the nanoribbons 224 of the stack 223-2 within the individual opening 228. Two individually controllable gate control lines are then coupled to the channel portion of each of the two such transistors, represented in FIG. 5C with two individually controllable conductive contacts 234-1 and 234-5 coupled to the channel portion of the first transistor in the individual opening 228, and with two individually controllable conductive contacts 234-4 and 234-6 coupled to the channel portion of the second transistor in the individual opening 228. The two-transistor per opening 228 implementation of FIG. 5C is similar to that shown in FIG. 2F, except that in FIG. 2F, for a given transistor, two gate control lines are provided as, or coupled to, conductive materials extending vertically along two different sidewalls (i.e., opposite sidewalls) of a stack 223, whereas, in FIG. 5C, for a given transistor, two gate control lines are provided as, or coupled to, conductive materials extending vertically along a single sidewall (i.e., opposite sidewalls) of a stack 223. Furthermore, the first S/D regions of the transistors in the embodiment of FIG. 5C are at the sidewalls of the nanoribbons 224, wherein, for FIG. 2F, both first and second S/D regions of the transistors are in portions of the nanoribbons 224 in the planes in front and behind the plane of the cross-sectional side view of FIG. 2F. The second S/D regions of the transistors in the embodiment of FIG. 5C may be in portions of the nanoribbons 224 in a plane in front or behind the plane of the cross-sectional side view of FIG. 5C, e.g., as described above with reference to the S/D regions 114 shown in FIG. 1.

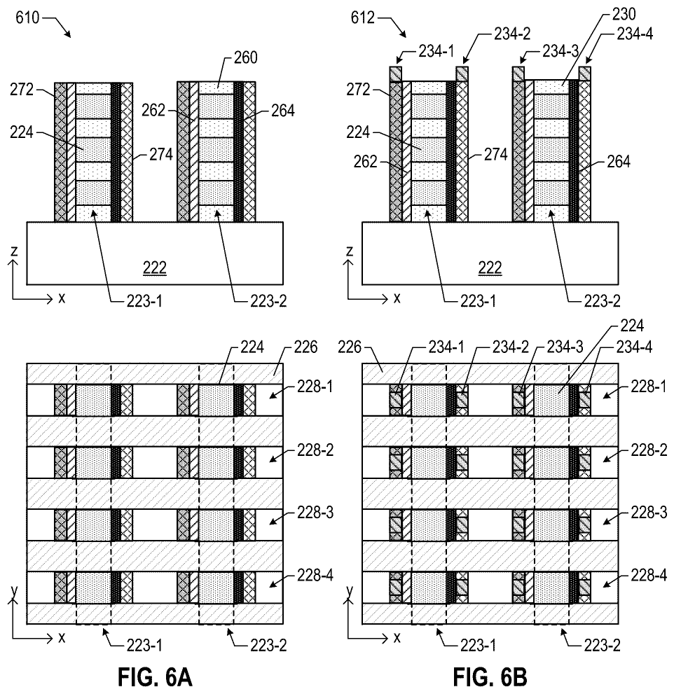

FIGS. 6A-6B illustrate cross-sectional side views and top-down views of example IC structures memory devices at various stages of fabrication according to the fifth embodiment.

The fabrication according to the fifth embodiment may begin with any suitable processes to provide an IC structure 610 shown in FIG. 6A. As shown in FIG. 6A, the IC structure 610 may include a support with one or more stacks 223 of the nanoribbons 224 (shown as two stacks, 223-1 and 223-2), with an insulator material and a conductive material on the sidewalls of each of the stacks 223, and with an insulator material between adjacent vertically-stacked nanoribbons 224 of an individual stack 223. The IC structure 610 is similar to the IC structure 210, shown in FIG. 2E, except for the following differences.

In FIG. 2E, a single insulator material, the insulator material 230 is provided between adjacent vertically-stacked nanoribbons 224 of the individual stack 223s and on the sidewalls of each of the stacks 223. In contrast, the IC structure 610 is more versatile in that it allows implementing a first insulator material 260 between adjacent vertically-stacked nanoribbons 224 of an individual stack 223, a second insulator material 262 on one of the sidewalls of the stacks 223, and a third insulator material 264 on the other one of the sidewalls of the stacks 223, where material compositions of any pair of these insulator materials may, but does not have to be, the same. In various embodiments, the first insulator material 260, the second insulator material 262, and the third insulator material 264 may include any of the materials described with reference to the insulator material 230. For example, in some embodiments, one of the second insulator material 262 and the third insulator material 264 may include a ferroelectric or an antiferroelectric material, while the other one may include a dielectric material that is not a ferroelectric or an antiferroelectric material. In some such embodiments, the first insulator material 260 may also include a dielectric material that is not a ferroelectric or an antiferroelectric material. In other embodiments, two or more of the first insulator material 260, the second insulator material 262, and the third insulator material 264 may include ferroelectric or antiferroelectric materials (which may be of different material compositions in the two), while the third one may include a dielectric material that is not a ferroelectric or an antiferroelectric material. In still other embodiments, all three of the first insulator material 260, the second insulator material 262, and the third insulator material 264 may include ferroelectric or antiferroelectric materials (which may be of different material compositions in the three). In some embodiments, a thickness of the second insulator material 262 at one of the sidewalls of the stacks 223 and/or a thickness of the third insulator material 264 at the other one of the sidewalls of the stacks 223 of the embodiment shown in FIG. 6A may be as that described above for the analogous thicknesses of other insulator materials on the sidewalls of the stacks 223.

Furthermore, in FIG. 2E, a single conductive material, the conductive material 232 is provided on both sidewalls of each of the stacks 223. In contrast, the IC structure 610 is more versatile in that it allows implementing a first conductive material 272 on one of the sidewalls of the stacks 223, and a second conductive material 274 on the other one of the sidewalls of the stacks 223, where material compositions of these two conductive materials may, but does not have to be, the same. In various embodiments, the first conductive material 272 and the second conductive material 274 may include any of the materials described with reference to the conductive material 232. In some embodiments, a thickness of the first conductive material 272 at one of the sidewalls of the stacks 223 and/or a thickness of the second conductive material 274 at the other one of the sidewalls of the stacks 223 of the embodiment shown in FIG. 6A may be as that described above for the analogous thicknesses of other conductive materials on the sidewalls of the stacks 223.

Similar to FIG. 2E, in FIG. 6A, in some embodiments, the second insulator material 262 may be between (and in physical contact with) the sidewalls of the nanoribbons 224 on one side and either the first conductive material 272 or the second conductive material 274 on the other side. Similarly, in some embodiments, the third insulator material 264 may be between (and in physical contact with) the sidewalls of the nanoribbons 224 on one side and either the first conductive material 272 or the second conductive material 274 on the other side.

The fabrication according to the fifth embodiment may further include coupling individual gate control lines to the portions of the first conductive material 272 and second conductive material 274 on the opposite sidewalls of an individual stack 223. A result of this process is shown in FIG. 6B, illustrating an IC structure 612 that is substantially the same as the IC structure 212 except for the modifications in terms of the first insulator material 260, the second insulator material 262, and the third insulator material 264 replacing a single insulator material 230, and in terms of the first conductive material 272 and second conductive material 274 replacing a single conductive material 232. In particular, FIG. 6B illustrates a conductive contact 234-1 connected (e.g., being in conductive contact with) to a portion of the first conductive material 272 extending vertically along the first sidewall of the stack 223-1, a conductive contact 234-2 connected (e.g., being in conductive contact with) to a portion of the second conductive material 274 extending vertically along the second sidewall of the stack 223-1, a conductive contact 234-3 connected (e.g., being in conductive contact with) to a portion of the first conductive material 272 extending vertically along the first sidewall of the stack 223-2, and a conductive contact 234-4 connected (e.g., being in conductive contact with) to a portion of the second conductive material 274 extending vertically along the second sidewall of the stack 223-2.

In other embodiments of the IC devices of FIGS. 6A-6B, arrangement of the second insulator material 262 and the third insulator material 264, and/or arrangement of the first conductive material 272 and the second conductive material 274 may be different than what is shown. For example, in some embodiments, the same insulator material (e.g., either the second insulator material 262 or the third insulator material 264) may be on sidewalls of the stack 223-1 and 223-2 that are closest to one another (e.g., on the right sidewall of the stack 223-1 and the left sidewall of the stack 223-2), while the other insulator material (i.e., the other one of the second insulator material 262 and the third insulator material 264) may be on sidewalls of the stack 223-1 and 223-2 that are farthest apart from one another (e.g., on the left sidewall of the stack 223-1 and the right sidewall of the stack 223-2). Similarly, in some embodiments, the same conductive material (e.g., either the second conductive material 272 or the third conductive material 274) may be on sidewalls of the stack 223-1 and 223-2 that are closest to one another (e.g., on the right sidewall of the stack 223-1 and the left sidewall of the stack 223-2), while the other conductive material (i.e., the other one of the second conductive material 272 and the third conductive material 274) may be on sidewalls of the stack 223-1 and 223-2 that are farthest apart from one another (e.g., on the left sidewall of the stack 223-1 and the right sidewall of the stack 223-2). In such embodiments, the arrangement of the second insulator material 262 and the third insulator material 264 may be either as shown in FIGS. 6A-6B, or different, e.g., as described above. Other descriptions provided for FIG. 2F are applicable to FIG. 6B and, for the sake of brevity, are not repeated.

Various arrangements of the IC devices as illustrated in FIGS. 1-6 do not represent an exhaustive set of IC devices that may implement memory devices with programmable gates as described herein, but merely provide examples of such devices/structures/assemblies. For example, while FIGS. 3A-3F illustrate a single conductive material 232 on different sidewalls of the insulator material 230, in other embodiments, the single conductive material 232 may be replaced with two different conductive materials, e.g., as described with reference to the first conductive material 272 and the second conductive material 274 of FIGS. 6A-6B. Similarly, while FIGS. 4A-4C and FIGS. 5A-5C illustrate a single second insulator material 240 on different sidewalls of the conductive material 232, in other embodiments, the single second insulator material 240 may be replaced with two different insulator materials, e.g., as described with reference to the second insulator material 262 and the third insulator material 264 of FIGS. 6A-6B. Other combinations on the choice of insulator materials and/or conductive materials as described with reference to FIGS. 6A-6B are possible with the embodiments shown in FIGS. 2A-2F, FIGS. 3A-3F, FIGS. 4A-4C, and FIGS. 5A-5C, all of which being within the scope of the present disclosure. The number and positions of various elements shown in FIGS. 1-6 is purely illustrative and, in various other embodiments, other numbers of these elements, provided in other locations relative to one another may be used in accordance with the general architecture considerations described herein.

Arrangements with one or more memory devices with programmable gates as disclosed herein may be included in any suitable electronic device. FIGS. 7-11 illustrate various examples of devices and components that may include one or more memory devices with programmable gates as disclosed herein, e.g., any of the IC structures 212, 312, 414, 518, or 612, or any combination of such IC structures.

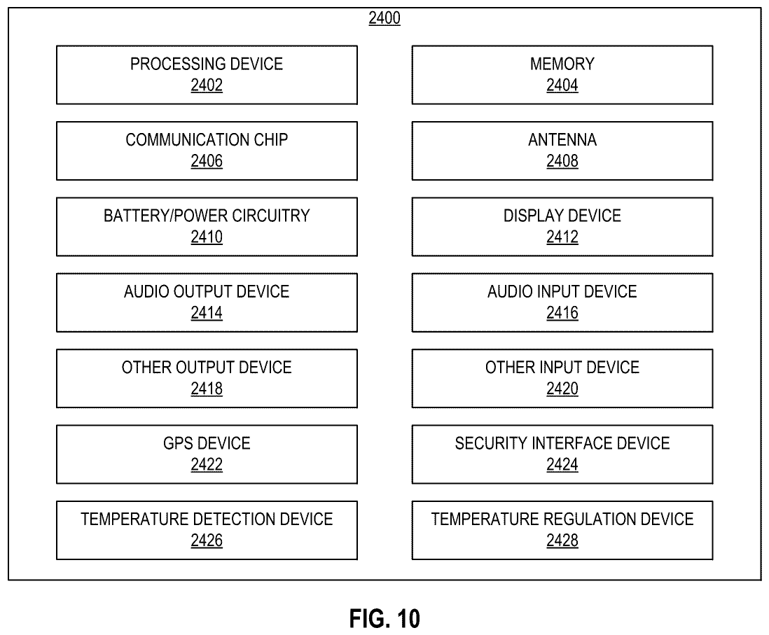

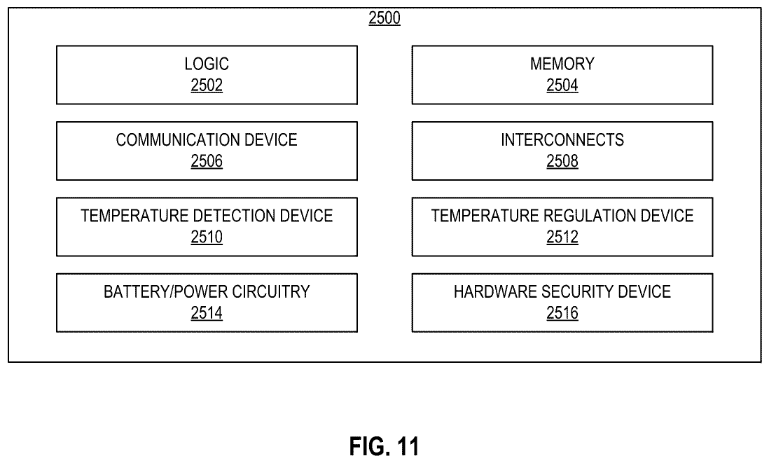

FIG. 7 illustrates top views of a wafer 2000 and dies 2002 that may include one or more memory devices with programmable gates in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 8. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more memory devices with programmable gates as described herein). After the fabrication of the semiconductor product is complete (e.g., after manufacture of any embodiment of the IC structures 212, 312, 414, 518, or 612, or any combination of such IC structures), the wafer 2000 may undergo a singulation process in which each of the dies 2002 is separated from one another to provide discrete “chips” of the semiconductor product. In particular, devices that include one or more memory devices with programmable gates as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a floating body memory device with programmable gates as described herein), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 10 or the logic circuitry 2502 of FIG. 11) or other logic that is configured to store information in the memory devices or execute instructions stored in the memory array.

FIG. 8 is a side, cross-sectional view of an example IC package 2200 that may include one or more memory devices with programmable gates in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 8 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 8 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

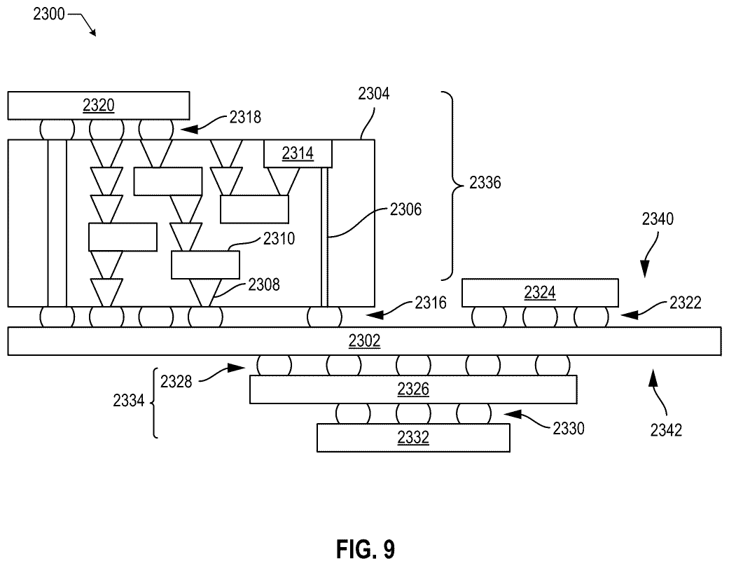

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 8 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 9.

The dies 2256 may take the form of any of the embodiments of the die 2002 discussed herein (e.g., may include any of the embodiments of the memory devices with programmable gates as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more memory devices with programmable gates, e.g., as discussed above; in some embodiments, at least some of the dies 2256 may not include any memory devices with programmable gates.

The IC package 2200 illustrated in FIG. 8 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 8, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 9 is a cross-sectional side view of an IC device assembly 2300 that may include components having one or more memory devices with programmable gates in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more memory devices with programmable gates in accordance with any of the embodiments disclosed herein; e.g., any of the IC packages discussed below with reference to the IC device assembly 2300 may take the form of any of the embodiments of the IC package 2200 discussed above with reference to FIG. 8 (e.g., may include one or more memory devices with programmable gates provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 9 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 7), an IC device, or any other suitable component. In particular, the IC package 2320 may include one or more memory devices with programmable gates as described herein. Although a single IC package 2320 is shown in FIG. 9, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 9, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 9 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 10 is a block diagram of an example computing device 2400 that may include one or more components including memory devices with programmable gates in accordance with any of the embodiments disclosed herein. For example, any suitable ones of the components of the computing device 2400 may include a die (e.g., the die 2002 of FIG. 7) having one or more memory devices with programmable gates as described herein. Any one or more of the components of the computing device 2400 may include, or be included in, an IC package 2200 of FIG. 8 or an IC device assembly 2300 of FIG. 9.

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM. In some embodiments, the memory 2404 may include one or more memory devices with programmable gates as described herein.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 11 is a block diagram of an example processing device 2500 that may include one or more components including memory devices with programmable gates in accordance with any of the embodiments disclosed herein. For example, any suitable ones of the components of the processing device 2500 may include a die (e.g., the die 2002 of FIG. 7) having one or more memory devices with programmable gates as described herein. Any one or more of the components of the processing device 2500 may include, or be included in, an IC device assembly 2300 (FIG. 9). Any one or more of the components of the processing device 2500 may include, or be included in, an IC package 2200 of FIG. 8 or an IC device assembly 2300 of FIG. 9. Any one or more of the components of the processing device 2500 may include, or be included in, a computing device 2400 of FIG. 10; for example, the processing device 2500 may be the processing device 2402 of the computing device 2400.

A number of components are illustrated in FIG. 11 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 11, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 10). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502. In some embodiments, the memory 2504 may include one or more memory devices with programmable gates.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, e.g., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 10). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc.

The processing device 2500 may include a temperature detection device 2510 which may be implemented substantially as described above with reference to the temperature detection device 2426 of FIG. 10 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 10 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 10. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 10. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC structure, including a substrate (or, more generally, a support structure such as a substrate, a wafer, a die, or a chip) and a stack including a plurality of nanoribbons that are vertically stacked above one another over the substrate. In a cross-section of the IC structure along a plane perpendicular to a longitudinal axis of the stack and including vertically-stacked portions of the plurality of nanoribbons of the stack, the IC structure includes an insulator material between adjacent nanoribbons of the stack, a first conductive material extending vertically along a first sidewall or a second sidewall of the stack, and a second conductive material extending vertically along the first sidewall or the second sidewall of the stack, where the second conductive material is electrically isolated from the first conductive material.

Example 2 provides the IC structure according to example 1, where, in the cross-section, the insulator material fills all space between the adjacent nanoribbons of the stack (i.e., there is no conductive material between the adjacent nanoribbons of the stack, which is in contrast to conventional floating body memory cells where a wordline would wrap around individual vertically-stacked portions of the plurality of nanoribbons of the stack).

Example 3 provides the IC structure according to examples 1 or 2, where, in the cross-section: the first conductive material extends vertically along the first sidewall, and the second conductive material extends vertically along the second sidewall (i.e., the first conductive material is closer to the first sidewall than the second sidewall, and the second conductive material is closer to the second sidewall than the first sidewall), and the insulator material provides the electrical isolation between the first and second conductive materials.

Example 4 provides the IC structure according to example 3, where, in the cross-section: the insulator material between the adjacent nanoribbons of the stack is a first insulator material, and the IC structure further includes a second insulator material is between the first sidewall of the stack and the first conductive material, and a third insulator material is between the second sidewall of the stack and the second conductive material.

Example 5 provides the IC structure according to example 4, where a material composition of the second insulator material is different from a material composition of the third insulator material.

Example 6 provides the IC structure according to examples 4 or 5, where a material composition of the first insulator material is different from a material composition of the second insulator material and/or a material composition of the third insulator material.

Example 7 provides the IC structure according to any one of examples 4-6, where one of the first insulator material, the second insulator material, and the third insulator material includes a ferroelectric material or an antiferroelectric material, and one other one of the first insulator material, the second insulator material, and the third insulator material includes an insulator material that is not a ferroelectric material or an antiferroelectric material.

Example 8 provides the IC structure according to any one of examples 4-7, where one of the second insulator material and the third insulator material includes a ferroelectric material or an antiferroelectric material, and another one of the second insulator material and the third insulator material includes an insulator material that is not a ferroelectric material or an antiferroelectric material.

Example 9 provides the IC structure according to examples 1 or 2, where, in the cross-section: the first conductive material extends vertically along the first sidewall, the second conductive material extends vertically along the first sidewall (i.e., both the first and second conductive materials are closer to the first sidewall than the second sidewall), the insulator material is a first insulator material, and the IC structure further includes a second insulator material between the first conductive material and the second conductive material, where the second insulator material provides the electrically isolation between the first and second conductive materials.

Example 10 provides the IC structure according to example 9, where a material composition of the second insulator material is different from a material composition of the first insulator material.

Example 11 provides the IC structure according to examples 9 or 10, where one of the first insulator material and the second insulator material includes a ferroelectric material or an antiferroelectric material, and another one of the first insulator material and the second insulator material includes an insulator material that is not a ferroelectric material or an antiferroelectric material.

Example 12 provides the IC structure according to any one of examples 9-11, where, in the cross-section, the IC structure further includes a conductive material extending vertically along the second sidewall.

Example 13 provides the IC structure according to example 12, where, in the cross-section, the IC structure further includes an insulator material between the conductive material and the first insulator material.

Example 14 provides the IC structure according to examples 12 or 13, where portions of the vertically-stacked portions of the plurality of nanoribbons of the stack at the second sidewall include one or more semiconductor materials with dopant atoms in a concentration of at least 1×1018 dopant atoms per cubic centimeter.

Example 15 provides an IC structure, including a support structure, e.g., a die, a substrate, a wafer, or a chip; a first stack including a first plurality of nanoribbons that are vertically stacked above one another over the support structure; and a second stack including a second plurality of nanoribbons that are vertically stacked above one another over the support structure; where, in a cross-section of the IC structure along a plane perpendicular to a longitudinal axis of the first stack and including vertically-stacked portions of the first plurality of nanoribbons of the first stack and vertically-stacked portions of the second plurality of nanoribbons of the second stack, the IC structure includes an insulator material between adjacent nanoribbons of the first stack, between adjacent nanoribbons of the second stack, and between the first stack and the second stack, a first conductive material extending vertically along a first sidewall of the first stack, where the first sidewall of the first stack is further away from the second stack than a second sidewall of the first stack, and a second conductive material extending vertically along a second sidewall of the second stack, where the second sidewall of the second stack is further away from the first stack than a first sidewall of the second stack. The first conductive material may be coupled to, or may implement, a first gate control line coupled to the gate of a transistor, while the second conductive material may be coupled to, or may implement, a second gate control line coupled to the gate of the transistor. Because the second conductive material is electrically isolated from the first conductive material, the first and a second gate control lines may be individually controllable, thus realizing a memory device with a programmable gate.

Example 16 provides the IC structure according to example 15, where, in the cross-section, the insulator material fills all space between the adjacent nanoribbons of the first stack, between the adjacent nanoribbons of the second stack, and between the first stack and the second stack (i.e., there is no conductive material between the adjacent nanoribbons of the first or second stacks or between the first and second sacks).

Example 17 provides the IC structure according to examples 15 or 16, where the insulator material is a first insulator material and where, in the cross-section, the IC structure further includes a third conductive material extending vertically along the first sidewall of the first stack, a second insulator material between the first conductive material and the third conductive material, where the second insulator material provides the electrically isolation between the first and third conductive materials.

Example 18 provides the IC structure according to example 17, where a material composition of the second insulator material is different from a material composition of the first insulator material, e.g., where one of the first insulator material and the third insulator material includes a ferroelectric material or an antiferroelectric material, and another one of the first insulator material and the third insulator material includes an insulator material that is not a ferroelectric material or an antiferroelectric material.

Example 19 provides an IC structure, including a support structure, e.g., a substrate; and a memory cell over the substrate, where the memory cell includes a transistor having a channel region, a first gate control line coupled to the channel region, and a second gate control line, electrically isolated from the first gate control line, coupled to the channel region.

Example 20 provides the IC structure according to example 19, where: the IC structure includes a stack of nanoribbons over the substrate, a first conductive material, a second conductive material, and an insulator material, the channel region includes vertically-stacked portions of the nanoribbons of the stack, the first conductive material extends along a first sidewall or a second sidewall of the stack, the second conductive material extends along the first sidewall or the second sidewall of the stack, and the insulator material extends between adjacent nanoribbons of the nanoribbons of the stack.

Example 21 provides an IC package, including an IC die, including an IC structure; and a further component, coupled to the IC die, where the IC structure is an IC structure according to any one of the preceding examples.

Example 22 provides the IC package according to example 21, where the further component is one of a package substrate, an interposer, or a further IC die.

Example 23 provides an electronic device, including a carrier substrate; and one or more of the IC structures according to any one of the preceding examples and/or the IC package according to any one of the preceding claims, coupled to the carrier substrate.

Example 24 provides the electronic device according to example 23, where the carrier substrate is a motherboard.

Example 25 provides the electronic device according to example 23, where the carrier substrate is a PCB.

Example 26 provides the electronic device according to any one of examples 23-25, where the electronic device is a wearable electronic device (e.g., a smart watch) or handheld electronic device (e.g., a mobile phone).

Example 27 provides the electronic device according to any one of examples 23-26, where the electronic device further includes one or more communication chips and an antenna.

Example 28 provides the electronic device according to any one of examples 23-27, where the electronic device is memory device.

Example 29 provides the electronic device according to any one of examples 23-27, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 30 provides the electronic device according to any one of examples 23-27, where the electronic device is a computing device.

Example 31 provides the electronic device according to any one of examples 23-30, where the electronic device is included in a base station of a wireless communication system.

Example 32 provides the electronic device according to any one of examples 23-30, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a substrate; and
a stack comprising a plurality of nanoribbons vertically stacked above one another over the substrate,
wherein, in a cross-section of the IC structure along a plane perpendicular to a longitudinal axis of the stack and including vertically stacked portions of the plurality of nanoribbons, the IC structure includes:
an insulator material between adjacent nanoribbons of the stack,
a first conductive material extending vertically along a first sidewall or a second sidewall of the stack, and
a second conductive material extending vertically along the first sidewall or the second sidewall of the stack, wherein the second conductive material and the first conductive material are separated by one or more insulators.

2. The IC structure according to claim 1, wherein, in the cross-section, the insulator material fills space between the adjacent nanoribbons of the stack.

3. The IC structure according to claim 1, wherein:
the first conductive material extends vertically along the first sidewall, and
the second conductive material extends vertically along the second sidewall.

4. The IC structure according to claim 3, wherein:
the insulator material between the adjacent nanoribbons of the stack is a first insulator material, and
the IC structure further includes:
a second insulator material is between the first sidewall of the stack and the first conductive material, and
a third insulator material is between the second sidewall of the stack and the second conductive material.

5. The IC structure according to claim 4, wherein a material composition of the second insulator material is different from a material composition of the third insulator material.

6. The IC structure according to claim 4, wherein a material composition of the first insulator material is different from a material composition of the second insulator material or a material composition of the third insulator material.

7. The IC structure according to claim 4, wherein one of the first insulator material, the second insulator material, and the third insulator material includes a ferroelectric material or an antiferroelectric material, and one other one of the first insulator material, the second insulator material, and the third insulator material includes an insulator material that is not a ferroelectric material or an antiferroelectric material.

8. The IC structure according to claim 4, wherein one of the second insulator material and the third insulator material includes a ferroelectric material or an antiferroelectric material, and another one of the second insulator material and the third insulator material includes an insulator material that is not a ferroelectric material or an antiferroelectric material.

9. The IC structure according to claim 1, wherein:
the first conductive material extends vertically along the first sidewall,
the second conductive material extends vertically along the first sidewall,
the insulator material is a first insulator material, and
the IC structure further includes a second insulator material between the first conductive material and the second conductive material.

10. The IC structure according to claim 9, wherein a material composition of the second insulator material is different from a material composition of the first insulator material.

11. The IC structure according to claim 9, wherein one of the first insulator material and the second insulator material includes a ferroelectric material or an antiferroelectric material, and another one of the first insulator material and the second insulator material includes an insulator material that is not a ferroelectric material or an antiferroelectric material.

12. The IC structure according to claim 9, wherein, in the cross-section, the IC structure further includes a conductive material extending vertically along the second sidewall.

13. The IC structure according to claim 12, wherein, in the cross-section, the IC structure further includes an insulator material between the conductive material and the first insulator material.

14. The IC structure according to claim 12, wherein portions of the vertically stacked portions of the plurality of nanoribbons of the stack at the second sidewall include one or more semiconductor materials with dopant atoms in a concentration of at least 1×10¹⁸ dopant atoms per cubic centimeter.

15. An integrated circuit (IC) structure, comprising:
a die;
a first stack comprising a first plurality of nanoribbons that are vertically stacked above one another over the die; and
a second stack comprising a second plurality of nanoribbons that are vertically stacked above one another over the die,
wherein, in a cross-section of the IC structure along a plane perpendicular to a longitudinal axis of the first stack and including vertically stacked portions of the first plurality of nanoribbons and vertically stacked portions of the second plurality of nanoribbons, the IC structure includes:
an insulator material between adjacent nanoribbons of the first stack, between adjacent nanoribbons of the second stack, and between the first stack and the second stack,
a first conductive material extending vertically along a first sidewall of the first stack, wherein the first sidewall of the first stack is further away from the second stack than a second sidewall of the first stack, and
a second conductive material extending vertically along a second sidewall of the second stack, wherein the second sidewall of the second stack is further away from the first stack than a first sidewall of the second stack.

16. The IC structure according to claim 15, wherein, in the cross-section, the insulator material fills space between the adjacent nanoribbons of the first stack, between the adjacent nanoribbons of the second stack, and between the first stack and the second stack.

17. The IC structure according to claim 15, wherein the insulator material is a first insulator material and wherein, in the cross-section, the IC structure further includes:
a third conductive material extending vertically along the first sidewall of the first stack, and
a second insulator material between the first conductive material and the third conductive material.

18. The IC structure according to claim 17, wherein a material composition of the second insulator material is different from a material composition of the first insulator material.

19. An integrated circuit (IC) structure, comprising:
a substrate; and
a memory cell over the substrate, wherein the memory cell includes:
a transistor having a channel region,
a first gate control line coupled to the channel region, and
a second gate control line, electrically isolated from the first gate control line, coupled to the channel region.

20. The IC structure according to claim 19, wherein:
the IC structure includes a stack of nanoribbons over the substrate, a first conductive material, a second conductive material, and an insulator material,
the channel region includes vertically stacked portions of the nanoribbons of the stack,
the first conductive material extends along a first sidewall or a second sidewall of the stack,
the second conductive material extends along the first sidewall or the second sidewall of the stack, and
the insulator material extends between adjacent nanoribbons of the nanoribbons of the stack.
